(19) United States
(12) Patent Application Publication
(10) Pub. No.: US 2025/0095996 A1
(43) Pub. Date: Mar. 20, 2025

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Takeyoshi NISHIMURA, Matsumoto-city (JP)

(73) Assignee: FUJI ELECTRIC CO., LTD., Kawasaki-shi (JP)

(21) Appl. No.: 18/962,850

(22) Filed: Nov. 27, 2024

Related U.S. Application Data
(63) Continuation of application No. PCT/JP2023/041006, filed on Nov. 14, 2023.

(30) Foreign Application Priority Data
Dec. 27, 2022 (JP) 2022-210419

(51) Int. Cl. H01L 21/28; H01L 21/285; H01L 21/324; H01L 21/768; H01L 23/485; H10D 30/66

(52) U.S. Cl. CPC H01L 21/28061; H01L 21/28518; H01L 21/324; H01L 21/7685; H01L 21/76856; H01L 23/485; H10D 30/668

(57) ABSTRACT

A front electrode is in ohmic contact with a semiconductor substrate via a contact structure having a TiSix film, a TiN film, and a metal plug. The TiSix film is deposited directly by sputtering, and is provided along sidewalls (side surfaces of an interlayer insulating film) of a contact hole to an inner wall of a source contact trench. Ends of the TiSix film terminate on the side surfaces of the interlayer insulating film. A thickness of the TiSix film is uniform from the sidewalls of the contact hole to sidewalls of the source contact trench. The TiN film is provided along a surface of the TiSix film. The metal plug is embedded in the contact hole and the source contact trench, onto the TiN film.

### CROSS REFERENCE TO RELATED APPLICATIONS

This is a continuation application of International Application PCT/JP2023/041006 filed on Nov. 14, 2023 which claims priority from a Japanese Patent Application No. 2022-210419 filed on Dec. 27, 2022, the contents of which are incorporated herein by reference.

### BACKGROUND OF THE INVENTION

### 1. Field of the Invention

Embodiments of the present disclosure relate to a semiconductor device and a method of manufacturing a semiconductor device.

### 2. Description of the Related Art

Conventionally, semiconductor devices have been proposed in which an adhesive layer containing titanium (Ti) and a buffer layer containing titanium-silicon-nitride (Ti—Si—N) are provided between a front electrode and a semiconductor substrate and in which a contact structure including a titanium silicide (TiSi) film formed by converting a Ti film into a silicide or a TiSi film formed by plasma enhanced chemical vapor deposition (PECVD) is provided (for example, refer to Japanese Laid-Open Patent Publication No. H10-321812, Japanese Laid-Open Patent Publication No. H10-79431, Japanese Laid-Open Patent Publication No. H10-79481, Japanese Laid-Open Patent Publication No. H7-297136, and Japanese Laid-Open Patent Publication No. 2015-124397). Further, a semiconductor device having a gate electrode that includes a TiSi film deposited by sputtering has been proposed (for example, refer to Japanese Patent No. 3988342).

### SUMMARY OF THE INVENTION

According to an embodiment of the present disclosure, a semiconductor device includes: a semiconductor substrate having a first main surface and a second main surface opposite to each other; a first semiconductor region of a first conductivity type, provided in the semiconductor substrate; a second semiconductor region of a second conductivity type, provided between the first main surface of the semiconductor substrate and the first semiconductor region; a device structure provided in the semiconductor substrate, at the first main surface thereof, the device structure having a pn junction between the second semiconductor region and the first semiconductor region; an interlayer insulating film provided at the first main surface of the semiconductor substrate, the interlayer insulating film covering the device structure; a contact hole penetrating through the interlayer insulating film in a depth direction and reaching the semiconductor substrate; a contact structure in contact with the semiconductor substrate in the contact hole; a first electrode electrically connected to the second semiconductor region via the contact structure; and a second electrode provided at the second main surface of the semiconductor substrate. The contact structure is configured by: a titanium silicide film in contact with the semiconductor substrate in the contact hole, the titanium silicide film extending along a surface of the interlayer insulating film including portions thereof along sidewalls of the contact hole; a titanium nitride film provided along a surface of the titanium silicide film; and a metal plug embedded in the contact hole onto the titanium nitride film.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a semiconductor device according to a first embodiment.

FIG. 2 is a cross-sectional view depicting a state of the semiconductor device according to the first embodiment during manufacture.

FIG. 3 is a cross-sectional view depicting a state of the semiconductor device according to the first embodiment during manufacture.

FIG. 4 is a cross-sectional view depicting a state of the semiconductor device according to the first embodiment during manufacture.

FIG. 5 is a cross-sectional view depicting a state of the semiconductor device according to the first embodiment during manufacture.

FIG. 6 is a cross-sectional view depicting a state of the semiconductor device according to the first embodiment during manufacture.

FIG. 7 is a cross-sectional view depicting a structure of a semiconductor device according to a second embodiment.

FIG. 8 is a cross-sectional view depicting a state of the semiconductor device according to the second embodiment during manufacture.

FIG. 9 is a figure depicting a relationship between crystal damage recovery of the semiconductor substrate by hydrogen annealing and a barrier metal.

FIG. 10 is a cross-sectional view depicting a structure of a first comparison example.

FIG. 11 is a cross-sectional view depicting a structure of a second comparison example.

FIG. 12 is a cross-sectional view depicting a state of the second comparison example during manufacture.

FIG. 13 is a cross-sectional view depicting a state of the second comparison example during manufacture.

FIG. 14 is a cross-sectional view depicting a state of the second comparison example during manufacture.

FIG. 15 is a cross-sectional view depicting a state of the second comparison example during manufacture.

FIG. 16 is a cross-sectional view depicting a state of the second comparison example during manufacture.

FIG. 17 is a cross-sectional view depicting a state of the second comparison example during manufacture.

FIG. 18 is a cross-sectional view depicting a state of the second comparison example during manufacture.

### DETAILED DESCRIPTION OF THE INVENTION

First, problems associated with the conventional techniques are discussed. In Japanese Laid-Open Patent Publication No. H10-321812, Japanese Laid-Open Patent Publication No. H10-79431, Japanese Laid-Open Patent Publication No. H10-79481, and Japanese Laid-Open Patent Publication No. H7-297136, the Ti film included in the stacked structure of the front electrode inhibits an effect of hydrogen annealing for recovering (repairing) crystal damage of the semiconductor substrate. Further, in Japanese Laid-Open Patent Publication No. H7-297136, locally generated stress in semiconductor substrate increases due to the volumetric expansion of the TiSi film caused by the conversion into a silicide. In Japanese Laid-Open Patent Publication No. 2015-124397, chlorine (Cl) contained in a feed gas composition in the PECVD for forming the TiSi film causes corrosion of the semiconductor substrate.

Here, an outline of an embodiment of the present disclosure is described. (1) A semiconductor device according to an embodiment of the present disclosure is as follows. In a semiconductor substrate, a first semiconductor region of a first conductivity type is provided. A second semiconductor region of a second conductivity type is provided between a first main surface (front surface) of the semiconductor substrate and the first semiconductor region. A device structure having a pn junction between the second semiconductor region and the first semiconductor region is provided in the semiconductor substrate, at the first main surface thereof. An interlayer insulating film is provided at the first main surface of the semiconductor substrate. The interlayer insulating film covers the device structure. A contact hole penetrates through the interlayer insulating film in a depth direction and reaches the semiconductor substrate. A contact structure is in contact with the semiconductor substrate in the contact hole.

A first electrode is electrically connected to the second semiconductor region via the contact structure. A second electrode is provided at a second main surface (back surface) of the semiconductor substrate. The contact structure is configured by a titanium silicide film, a titanium nitride film, and a metal plug. The titanium silicide film is in contact with the semiconductor substrate in the contact hole and extends along a surface of the interlayer insulating film including portions thereof along sidewalls of the contact hole. The titanium nitride film is provided along a surface of the titanium silicide film. The metal plug is embedded in the contact hole, onto the titanium nitride film.

According to the disclosure above, the first electrode and the semiconductor substrate are electrically connected via the TiSix film (titanium silicide film), whereby contact resistance between the first electrode and the semiconductor substrate is reduced. Further, according to the disclosure above, in forming the TiSix film, no particular high-temperature heat treatment such as for silicide conversion is necessary. Thus, stress locally generated in the semiconductor substrate may be suppressed. Further, no Ti film, which absorbs hydrogen, is formed at the surface of the interlayer insulating film and thus, recovery of crystal damage of the semiconductor substrate by hydrogen annealing is facilitated. Further, since no Ti film is formed at the surface of the interlayer insulating film, decreased adhesion of the interlayer insulating film due to the Ti film and the material gas reacting with each other during formation of the metal plug may be prevented.

(2) Further, the semiconductor device according to the present disclosure, in (1) above, further includes a contact trench of a predetermined depth provided in the semiconductor substrate, at the first main surface thereof, the contact trench being continuous with the contact hole. The titanium silicide film may be provided along sidewalls of the contact hole and an inner wall of the contact trench.

According to the disclosure above, the area of contact between the TiSix film and the semiconductor substrate increases and thus, increases in the contact resistance between the first electrode and the semiconductor substrate may be suppressed.

(3) Further, in the semiconductor device according to the present disclosure, in (2) above, the titanium silicide film has a thickness that may be uniform from the sidewalls of the contact hole to the sidewalls of the contact trench.

According to the disclosure above, stress applied to the interlayer insulating film and the semiconductor substrate along the sidewalls of the contact hole and the sidewalls of the contact trench is uniform.

(4) Further, in the semiconductor device according to the present disclosure, in (2) above, the interlayer insulating film may be positioned so as to not be more than 10nm from the contact trench in a direction parallel to the first main surface of the semiconductor substrate.

According to the disclosure above, step coverage of the metal plug is enhanced.

(5) Further, in the semiconductor device according to the present disclosure, in any one of (1) to (4) above, the titanium silicide film terminates at a side surface of the interlayer insulating film. The first electrode may be provided on a top surface of the interlayer insulating film and may be in contact with the interlayer insulating film.

According to the disclosure above, adhesion of the first electrode is enhanced and peeling of the first electrode from the interlayer insulating film may be suppressed.

(6) Further, in the semiconductor device according to the present disclosure, in any one of (1) to (4) above, the titanium silicide film covers an entire area of the surface of the interlayer insulating film. The first electrode is provided on the top surface of the interlayer insulating film via the titanium silicide film and the titanium nitride film.

According to the disclosure above, damage of the interlayer insulating film due to ultrasonic vibration during wire bonding to the first electrode may be suppressed.

(7) A method of manufacturing a semiconductor device according to an embodiment of the disclosure is as follows. As a first process, a second semiconductor region of a second conductivity type is formed in a semiconductor substrate having therein a first semiconductor region of a first conductivity type, the semiconductor substrate having a first main surface and a second main surface opposite to each other, the second semiconductor region being formed at the first main surface, in contact with the first semiconductor region, thereby forming a device structure having a pn junction between the second semiconductor region and the first semiconductor region. As a second process, an interlayer insulating film that covers the device structure is formed at the first main surface of the semiconductor substrate. As a third process, a contact hole that penetrates through the interlayer insulating film in a depth direction and reaches the semiconductor substrate is formed. As a fourth process, a contact structure that is in contact with the semiconductor substrate is formed in the contact hole.

As a fifth process, a first electrode that is electrically connected to the second semiconductor region via the contact structure is formed. As a first annealing process, a heat treatment under a hydrogen atmosphere is performed after the fifth process, thereby recovering crystal damage of the semiconductor substrate. The fourth process includes first, second, and third deposition processes. In the first deposition process, a first sputtering is performed, thereby depositing a titanium silicide film covering an entire area of a surface of the interlayer insulating film, the titanium silicide film being in contact with the semiconductor substrate in the contact hole. In the second deposition process, a second sputtering process is performed, thereby depositing a titanium nitride film on a surface of the titanium silicide film. In the third deposition process, the metal plug is embedded in the contact hole, onto the titanium nitride film. The contact structure includes the titanium silicide film, the titanium nitride film, and the metal plug.

According to the disclosure above, the first electrode and the semiconductor substrate are electrically connected via the TiSix film (titanium silicide film), whereby contact resistance between the first electrode and the semiconductor substrate is reduced. Further, according to the disclosure above, in the formation of the TiSix film, no particular high-temperature heat treatment, such as for silicide conversion is necessary. Thus, stress locally generated in the semiconductor substrate may be suppressed. Further, no Ti film, which absorbs hydrogen, is formed at the surface of the interlayer insulating film and thus, recovery of crystal damage of the semiconductor substrate by the hydrogen annealing is facilitated. Further, since no Ti film is formed at the surface of the interlayer insulating film, decreased adhesion of the interlayer insulating film due to the Ti film and the material gas reacting with each other during formation of the metal plug may be prevented.

(8) Further, the method of manufacturing the semiconductor device according to the present disclosure, in (7) above, further includes as a sixth process after the third process but before the fourth process, forming a contact trench of a predetermined depth in the semiconductor substrate at the first main surface thereof, the contact trench being continuous with the contact hole. In the first deposition process, the titanium silicide film may be formed along the surface of the interlayer insulating film and an inner wall of the contact trench.

According to the disclosure above, the area of contact between the TiSix film and the semiconductor substrate increases and thus, increases in the contact resistance between the first electrode and the semiconductor substrate may be suppressed.

(9) Further, the method of manufacturing the semiconductor device according to the present disclosure, in (8) above, may further include as a seventh process after the sixth process but before the fourth process, flattening the interlayer insulating film.

According to the disclosure above, embeddability of the metal plug into the contact trench may be enhanced.

(10) Further, in the method of manufacturing the semiconductor device according to the present disclosure, in any one of (7) to (9) above, the first deposition process and the second deposition process may be performed successively using a same sputtering device.

According to the disclosure above, the processes may be simplified and costs may be reduced.

(11) Further, in the method of manufacturing the semiconductor device according to the present disclosure, in any one of (7) to (10) above, the fourth process includes as a removal process, etching back of the titanium nitride film and the titanium silicide film using the metal plug as a mask and exposing a top surface of the interlayer insulating film. In the fifth process, the first electrode may be formed on the top surface of the interlayer insulating film, in contact with the interlayer insulating film.

According to the disclosure above, adhesion of the first electrode is enhanced and peeling of the first electrode from the interlayer insulating film may be suppressed.

(12) Further, in the method of manufacturing the semiconductor device according to the present disclosure, in any one of (7) to (11) above, the first deposition process may be performed under an atmosphere of a temperature not higher than 300 degrees C.

According to the disclosure above, stress locally generated in the semiconductor substrate may be suppressed.

(13) Further, the method of manufacturing the semiconductor device according to the present disclosure, in any one of (7) to (12) above, further includes as an irradiation process after the first annealing process, irradiating the semiconductor substrate with radiation. As a second annealing process, a heat treatment under a hydrogen atmosphere may be performed after the irradiation process, thereby adjusting a predetermined recovery characteristic of a parasitic diode formed by the pn junction.

According to the disclosure above, crystal damage, which is a factor causing decreases in the gate threshold voltage, may be recovered.

Findings underlying the present disclosure are discussed. Problems to be solved by the present embodiment, may include reducing contact (electrical contact) resistance between the front electrode and the semiconductor substrate, recovering (repairing) crystal damage by hydrogen annealing (heat treatment under a hydrogen atmosphere), the crystal damage occurring in the semiconductor substrate due to ion implantation of a dopant, exposure to radiation such as irradiation of electron beams, etc. Conventionally, titanium (Ti) has low contact resistance with an n-type silicon (Si) and thus, between the front electrode and the semiconductor substrate, while a method of forming a titanium silicide (TiSix) film by causing a Ti film to react with the semiconductor substrate (Si substrate) to form a silicide is known, volumetric expansion of the TiSix film caused by the silicide conversion increases the stress locally generated in the semiconductor substrate.

While the contact resistance between the TiSix film and the semiconductor substrate decreases the higher is the temperature of the heat treatment for the silicide conversion, the volumetric expansion of the TiSix film due to the silicide conversion further increases the stress locally generated in the semiconductor substrate. For example, when the contact resistance between the front electrode and the semiconductor substrate is reduced by increasing the area of contact with the semiconductor substrate by embedding a front electrode contact structure in a contact trench provided in the semiconductor substrate, at a front surface of the semiconductor substrate, the TiSix film is formed along an inner wall of the contact trench. The contact trench is narrow and shallow and thus, there is concern that the volumetric expansion of the TiSix film due to the silicide conversion may further increase the stress generated locally in the semiconductor substrate.

Further, in an instance in which the TiSix film is formed by causing a silicide conversion reaction with the semiconductor substrate, while the Ti film constituting a material film of the TiSix film is formed so as to cover an entire area of a surface of an interlayer insulating film, the Ti film easily absorbs hydrogen, which inhibits the effect of hydrogen annealing to recover crystal damage in the semiconductor substrate. Thus, even when the hydrogen annealing is performed, for example, recovery of characteristics such as the gate threshold voltage is difficult. In particular, in a product (semiconductor device) for which radiation exposure such as irradiation of electron beams has been performed to enhance switching characteristics such as a reverse recovery time trr of parasitic diodes (body diodes) formed by pn junctions (main junctions) between a p-type base region and an n⁻-type drift region, crystal damage that has occurred in the semiconductor substrate is not sufficiently repaired by the exposure to radiation.

Assuming that crystal damage in the semiconductor substrate will not be sufficiently recovered, it is possible to adjust a predetermined characteristic of the product to a predetermined value by, for example, excessively increasing the doping amount of a predetermined diffused region in the semiconductor substrate to set the predetermined characteristic higher in advance in anticipation of the amount of decrease due to crystal damage in the semiconductor substrate. However, in this instance, the predetermined characteristic may become higher than the predetermined value as a result of performing crystal damage recovery of the semiconductor substrate by hydrogen annealing and variation of the characteristic easily occurs in a reliability test such as a high-temperature application test. Thus, it is necessary to allow for a certain degree of variation of the characteristic caused by the crystal damage of the semiconductor substrate in product specifications, which results in inferior product reliability (the reliability of various characteristics evaluated in reliability tests such as high-temperature application tests). The present embodiment solves such problems.

Embodiments of a semiconductor device and a method of manufacturing a semiconductor device according to the present disclosure are described in detail with reference to the accompanying drawings. In the present description and accompanying drawings, layers and regions prefixed with n or p mean that majority carriers are electrons or holes. Additionally, +or − appended to n or p means that the impurity concentration is higher or lower, respectively, than layers and regions without +or −. In the description of the embodiments below and the accompanying drawings, main portions that are identical are given the same reference numerals and are not repeatedly described.

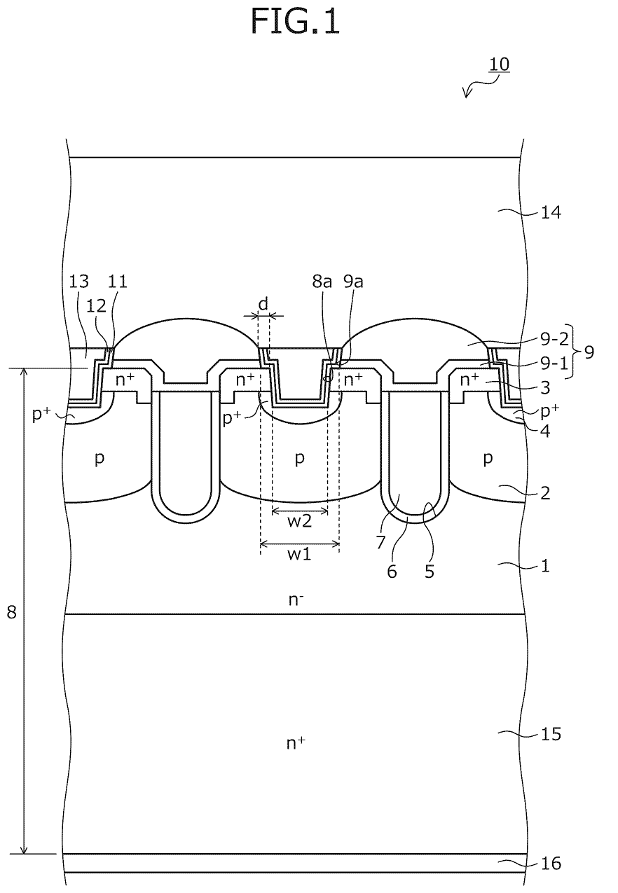

A semiconductor device according to a first embodiment that solves the problems above is described taking a metal oxide semiconductor field effect transistor (MOSFET) having an insulated gate with a three-layer metal-oxide-semiconductor structure as an example. FIG. 1 is a cross-sectional view depicting a structure of the semiconductor device according to the first embodiment. A semiconductor device 10 according to the first embodiment depicted in FIG. 1 is a vertical MOSFET with a trench gate structure (device structure) having a contact structure between a front electrode (first electrode) 14 and a semiconductor substrate (semiconductor chip) 8, the contact structure being formed by a titanium silicide (TiSix) film 11 (where, “x” is a positive number), a titanium nitride (TiN) film 12, and metal plugs (lead electrode portions) 13.

The semiconductor substrate 8 is, for example, an n⁻-type Si bulk substrate constituting an n⁻-type drift region (first semiconductor region) 1 or an Si substrate in which an n⁻-type epitaxial layer constituting the n⁻-type drift region 1 is stacked on an n⁺-type starting substrate (Si bulk substrate) constituting an n⁺-type drain region 15. In an instance in which the semiconductor substrate 8 is constituted by the n⁻-type Si bulk substrate constituting the n-type drift region 1, the n⁺-type drain region 15 is a diffused region formed by ion implantation in the semiconductor substrate 8, at a back surface of the semiconductor substrate 8. The n⁺-type drain region 15 is provided in the semiconductor substrate 8, at the back surface thereof and is in contact with the n⁻-type drift region 1. A back electrode (second electrode) 16 constituting a drain electrode is provided in an entire area of the back surface of the semiconductor substrate 8 and is in contact with the n⁺-type drain region 15.

The trench gate structure is configured by a p-type base region (second semiconductor region) 2, n⁺-type source regions 3, p⁺-type contact regions 4, trenches 5, gate insulating films 6, and gate electrodes 7, and is provided in the semiconductor substrate 8, at a front surface of the semiconductor substrate 8.

The p-type base region 2, the n⁺-type source regions 3, and the p⁺-type contact regions 4 are diffused regions formed in the semiconductor substrate 8, at the front surface thereof by ion implantation. The p-type base region 2 is provided between the front surface of the semiconductor substrate 8 and the n-type drift region 1 and is in contact with the n⁻-type drift region 1. The n⁺-type source regions 3 and the p⁺-type contact regions 4 are each selectively provided between the front surface of the semiconductor substrate 8 and the p-type base region 2 and are in contact with the p-type base region 2.

The n⁺-type source regions 3 and the p⁺-type contact regions 4 are in ohmic contact with the TiSix film 11. The p⁺-type contact regions 4 are provided apart from the trenches 5. From the front surface of the semiconductor substrate 8, the p⁺-type contact regions 4 reach positions closer to the n⁺-type drain region 15 (the back surface of the semiconductor substrate 8) than are the n⁺-type source regions 3. The p⁺-type contact regions 4 may be omitted. In this case, instead of the p+-type contact regions 4, the p-type base region 2 is in contact with the TiSix film 11. A portion of the semiconductor substrate 8 excluding the p-type base region 2, the n⁺-type source regions 3, the p⁺-type contact regions 4, and the n⁺-type drain region 15 constitutes the n-type drift region 1.

The trenches 5 penetrate through the n⁺-type source regions 3 and the p-type base region 2 in a depth direction from the front surface of the semiconductor substrate 8 and terminate in the n-type drift region 1. The gate insulating films 6 are provided along inner walls (sidewalls and bottoms) of the trenches 5. The gate electrodes 7 are embedded in the trenches 5, on the gate insulating films 6. The n⁺-type source regions 3, the p-type base region 2, and the n-type drift region 1 suffice to face the gate electrodes 7 with the gate insulating films 6 at the sidewalls of the trenches 5 intervening therebetween and upper ends (ends facing the openings of the trenches 5) of the gate insulating films 6 and the gate electrodes 7 may terminate at positions that are closer to the n⁺-type drain region 15 than to the front surface of the semiconductor substrate 8 (i.e., may terminate inside the trenches 5).

An interlayer insulating film 9 is provided at the front surface of the semiconductor substrate 8 and covers the gate electrodes 7. Contact holes 9a that penetrate through the interlayer insulating film 9 in the depth direction and reach the semiconductor substrate 8 are provided. In a cross-sectional view, each of the contact holes 9a may have a substantially rectangular shape or may have a substantially tapered shape (trapezoidal shape) having a width that gradually decreases along a direction to the semiconductor substrate 8. In an instance in which later-described source contact trenches 8a are provided, preferably, to improve the embeddability of the metal plugs 13 into the source contact trenches 8a, the thickness of the interlayer insulating film 9 may be relatively thin to reduce the aspect ratio (=depth/width) of the contact holes 9a, or top-surface corner portions (boundaries between a top surface and side surfaces) of the interlayer insulating film 9 may be rounded by reflow (flattening) of the interlayer insulating film 9.

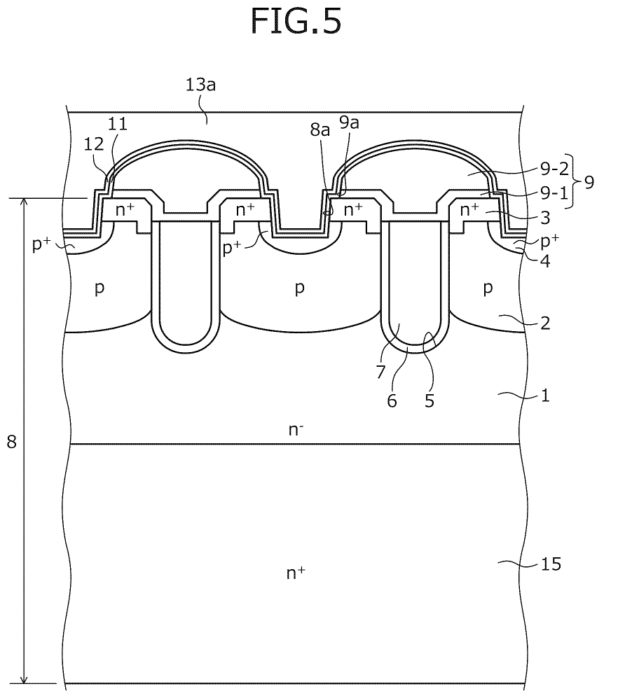

The interlayer insulating film 9, for example, is constituted by an oxide silicon (SiO₂) film by a borophosphosilicate glass (BPSG) film 9-2 or the like. For example, by setting a sum of the boron (B) concentration and phosphorus (P) concentration of the BPSG film 9-2 to, for example, 6 mol % or less and reflowing the BPSG film 9-2, a width w1 of each of the contact holes 9a becomes relatively wider on a first side thereof opposite to a second side thereof facing the semiconductor substrate 8 (i.e., portions continuous with the source contact trenches 8a). As a result, the contact holes 9a are less likely to be blocked when a W film 13a (see FIG. 5) is embedded, whereby the embeddability of the metal plugs 13 in the source contact trenches 8a may be improved.

The interlayer insulating film 9 may be a deposited SiO₂ film (hereinafter, high temperature oxide (HTO) film) 9-1 deposited by a general high temperature oxidation method. In this instance, the interlayer insulating film 9, for example, has a two-layer structure in which the HTO film 9-1 and the BPSG film 9-2 are sequentially stacked in the order stated. The HTO film 9-1, for example, has a same high film density and insulation performance as a thermal oxide film, and has better insulating properties than a deposited SiO₂ film formed by PECVD or sputtering. The interlayer insulating film 9 includes the HTO film 9-1, whereby the short-circuit capability between the electrodes (between the gate electrodes 7 and the front electrode 14) electrically insulated by the interlayer insulating film 9 is enhanced thereby enhancing the reliability of the semiconductor device 10. Instead of the HTO film 9-1, a deposited SiO₂ film containing a tetra ethoxy silane (TEOS) may be employed.

In the semiconductor substrate 8, at the front surface thereof, the source contact trenches 8a are provided continuous with the contact holes 9a of the interlayer insulating film 9. The source contact trenches 8a penetrate through the n⁺-type source regions 3 in the depth direction from the front surface of the semiconductor substrate 8 and terminate in the p⁺-type contact regions 4. From the front surface of the semiconductor substrate 8, the source contact trenches 8a reach positions closer to the n⁺-type drain region 15 than are the n⁺-type source regions 3. A bottom of each of the source contact trenches 8a is bordered by a corresponding one of the p⁺-type contact regions 4 and at an entire surface of the bottom of each of the source contact trenches 8a, the corresponding one of the p⁺-type contact regions 4 is exposed. At sidewalls of the source contact trenches 8a, the n⁺-type source regions 3 and the p⁺-type contact regions 4 are exposed. In a cross-sectional view, a shape of each of the source contact trenches 8a may be substantially rectangular or may be a substantially tapered shape having a width w2 that gradually decreases along a direction to the back surface of the semiconductor substrate 8.

The width w2 of each of the source contact trenches 8a is less than the width w1 of each of the contact holes 9a. A reason for this is that, after the source contact trenches 8a, which are continuous with the contact holes 9a, are formed by self-alignment using an etching mask used to form the contact holes 9a, the interlayer insulating film 9 (the BPSG film 9-2) is reflowed, whereby the side surfaces (the sidewalls of the contact holes 9a) of the interlayer insulating film 9 move (retreat) a predetermined distance d in a direction away from the source contact trenches 8a, whereby the width w1 of each of the contact holes 9a increases. A portion of the front surface of the semiconductor substrate 8, between a sidewall of any one of the contact holes 9a of the interlayer insulating film 9 and a sidewall of a corresponding one of the source contact trenches 8a is exposed for the distance d, which is not more than about 10 nm, and a step that is a difference in height occurs at said portion of the distance d.

The source contact trenches 8a are provided, whereby the area of contact between the TiSix film 11 and the semiconductor substrate 8 increases. Thus, even when the width w1 of each of the contact holes 9a is reduced due to decreasing a width between the trenches 5 that are adjacent to one another to reduce the size of the semiconductor device, increases in the contact resistance between the front electrode 14 and the semiconductor substrate 8 may be suppressed. Further, the source contact trenches 8a are provided, whereby during an off state, in the semiconductor substrate 8, holes in the n-type drift region 1 are easily led out to the front electrode 14 and avalanche tolerance is enhanced. In an instance in which the semiconductor device 10 is of a low-voltage class of about 250V or less, or in an instance of size reductions, avalanche breakdown easily occurs due to parasitic bipolar operation and thus, preferably, the source contact trenches 8a may be provided. Not only in instances of low-voltage classes but in all voltage breakdown classes, avalanche tolerance is enhanced by providing the source contact trenches 8a.

The source contact trenches 8a may be omitted. In this instance, at portions of the front surface of the semiconductor substrate 8 exposed in the contact holes 9a, the n⁺-type source regions 3 and the p⁺-type contact regions 4 are in ohmic contact with the TiSix film 11. The TiSix film 11 and the TIN film 12 are provided along the sidewalls (the side surfaces of the interlayer insulating film 9) and the bottoms (the portions of the front surface of the semiconductor substrate 8 exposed in the contact holes 9a) of the contact holes 9a and the metal plugs 13 are embedded in the contact holes 9a, onto the TIN film 12. Conditions for portions of the TiSix film 11 and the TIN film 12 along the sidewalls of the contact holes 9a and for portions thereof along the bottoms of the contact holes 9a are, respectively, the same as conditions for portions of the TiSix film 11 and the TiN film 12 along the sidewalls of the source contact trenches 8a and for portions thereof along the bottoms of the source contact trenches 8a.

On the sidewalls of the contact holes 9a (the side surfaces of the interlayer insulating film 9), on each continuous surface (hereinafter, step surface) between a sidewall of any one of the contact holes 9a and the sidewall of the corresponding one of the source contact trenches 8a, and on inner walls of the source contact trenches 8a, the TiSix film 11 and the TIN film 12 are sequentially stacked in the order stated. The TiSix film 11 and the TiN film 12 are not provided on the top surface of the interlayer insulating film 9. The top surface of the interlayer insulating film 9 is a portion of the surface of the interlayer insulating film 9 other than portions thereof constituting the sidewalls of the contact holes 9a. The front electrode 14 is in direct contact with the top surface of the interlayer insulating film 9 and thus, adhesion of the front electrode 14 is enhanced and peeling of the front electrode 14 from the interlayer insulating film 9 may be suppressed.

Further, the top surface of the interlayer insulating film 9 is free of the TiSix film 11 and the TiN film 12, whereby the TiSix film 11 and the TIN film 12, which are relatively hard, may be prevented from becoming damaged by ultrasonic vibration during wiring bonding to the front electrode 14. Further, the top surface of the interlayer insulating film 9 is free of the TiSix film 11 and the TiN film 12 and thus, for example, the effect of the hydrogen annealing for crystal damage recovery of the semiconductor substrate 8 is not inhibited. Thus, for example, crystal damage occurring in the semiconductor substrate 8 by performing carrier lifetime control of the n-type drift region 1 by exposure to radiation such as irradiation of electron beams may be recovered by hydrogen annealing and characteristics such as, for example, the gate threshold voltage may be restored.

The TiSix film 11 and the TiN film 12 are formed (deposited) by sputtering and portions thereof along the bottoms of the source contact trenches 8a tend to be thicker than portions thereof along the sidewalls of the contact holes 9a, the step surface (the front surface of the semiconductor substrate 8), and the source contact trenches 8a. The thickness of the TiSix film 11 and the thickness of the TiN film 12 is substantially uniform from the sidewalls of the contact holes 9a to the sidewalls of the source contact trenches 8a. Thus, at the sidewalls of the contact holes 9a and the sidewalls of the source contact trenches 8a, stress applied to the interlayer insulating film 9 and the semiconductor substrate 8 is uniform. The thickness being substantially uniform means substantially the same thickness within a range that includes allowable error due to manufacturing process variation.

The TiSix film 11 is in ohmic contact with the n⁺-type source regions 3 and the p⁺-type contact regions 4 at the inner walls of the source contact trenches 8a. The source contact trenches 8a are provided, whereby the area of contact between the TiSix film 11 and the semiconductor substrate 8 may be increased, thereby lowering the contact resistance between the TiSix film 11 and the semiconductor substrate 8. Thus, even when the width w1 of each of the contact holes 9a is reduced for reductions in size, increases in the contact resistance between the front electrode 14 and the semiconductor substrate 8 may be suppressed. The TIN film 12 is a barrier metal having a function of preventing diffusion of metal atoms from the front electrode 14 to the semiconductor substrate 8 and a function of preventing regions that face each other across the TiN film 12 from reacting with each other.

Ends of the TiSix film 11 terminate on the surface (for example, on the side surfaces of the interlayer insulating film 9) of the interlayer insulating film 9. Ends of the TiN film 12 terminate on the surface of the TiSix film 11. Adhesion of the TiSix film 11 to the interlayer insulating film 9 is higher than adhesion of the TIN film 12 to the interlayer insulating film 9. Thus, the TiSix film 11 is provided between the TiN film 12 and the interlayer insulating film 9, whereby adhesion of the front electrode 14 increases. The metal plugs 13 are provided on the TiN film 12 so as to be embedded in the contact holes 9a and the source contact trenches 8a. A height (position in the depth direction) of the top surface of each of the metal plugs 13 is a same as a height (position in the depth direction) of the ends of the TiN film 12 or is closer to the semiconductor substrate 8 than is the height of the ends of the TiN film 12. A material of the metal plugs 13 is, for example, tungsten (W), which has high embeddability and poor adhesion to the semiconductor substrate 8. The TiSix film 11 and the TiN film 12 are provided between the semiconductor substrate 8 and the metal plugs 13, whereby adhesion of the metal plugs 13 is enhanced.

The contact structure of the front electrode 14 is configured by the TiSix film 11, the TiN film 12, and the metal plugs 13. Without providing the metal plugs 13, the front electrode 14 may be embedded in the contact holes 9a and the source contact trenches 8a instead of the metal plugs 13. In this instance, the TIN film 12 may be omitted. In other words, the contact structure of the front electrode 14 may be constituted by only the TiSix film 11, which is in ohmic contact with the semiconductor substrate 8. The front electrode 14 is provided spanning and in contact with the top surface of the interlayer insulating film 9 and the top surfaces of the metal plugs 13. The front electrode 14 is, for example, an aluminum (Al) film or an Al alloy film. The front electrode 14 is electrically connected to the p-type base region 2, the n⁺-type source regions 3, and the p⁺-type contact regions 4 via the metal plugs 13, the TiN film 12, and the TiSix film 11 and functions as a source electrode.

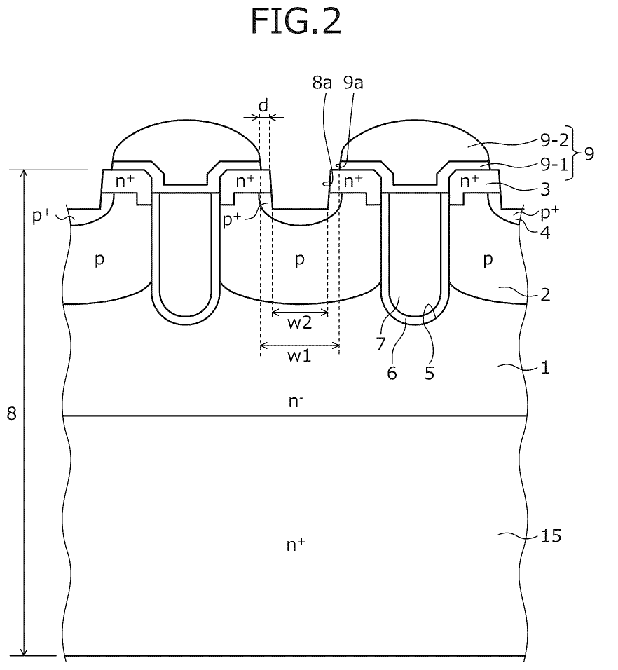

A method of manufacturing the semiconductor device 10 according to the first embodiment is described. FIGS. 2, 3, 4, 5, and 6 are cross-sectional views depicting states of the semiconductor device according to the first embodiment during manufacture. First, as depicted in FIG. 2, in the semiconductor substrate 8 constituting the n-type drift region 1, at the front surface of the semiconductor substrate 8, the trench gate structure, the interlayer insulating film 9 (the HTO film 9-1 and the BPSG film 9-2), and the contact holes 9a are formed by a general method (first, second, third processes). Next, the front surface of the semiconductor substrate 8 is etched using the same resist mask used to form the contact holes 9a, thereby forming the source contact trenches 8a continuous with the contact holes 9a (sixth process). Subsequently, the resist mask used to form the source contact trenches 8a is removed. In this instance, the resist mask may be removed after the contact holes 9a are formed and the source contact trenches 8a may be formed using the interlayer insulating film 9 as a mask. Next, the BPSG film 9-2 is reflowed while exposed surfaces of the semiconductor substrate 8 (here, the inner walls of the source contact trenches 8a) are oxidized by a heat treatment (seventh process). As a result, top-surface corner portions of the BPSG film 9-2 are rounded and side surfaces of the BPSG film 9-2 retreat the predetermined distance d in a direction away from the source contact trenches 8a. Next, in the contact holes 9a, portions of the oxide film covering the semiconductor substrate 8 are removed. At this time, together with the oxide film, the ends (portions exposed by the side surfaces of the BPSG film 9-2 retreating the predetermined distance d) of the HTO film 9-1 are also removed and the side surfaces of the HTO film 9-1 also retreat the predetermined distance d in a direction away from the source contact trenches 8a.

As described, the side surfaces of the interlayer insulating film 9 (the HTO film 9-1 and the BPSG film 9-2) retreat the predetermined distance d in a direction away from the source contact trenches 8a, whereby the width w1 of each of the contact holes 9a increases. As a result, at a subsequent process, embeddability of the W film 13a (refer to FIG. 5) into the source contact trenches 8a is enhanced, the W film 13a being deposited on the front surface of the semiconductor substrate 8. Further, the BPSG film 9-2 is reflowed while the exposed surfaces of the semiconductor substrate 8 are oxidized, whereby the distance d that the side surfaces of the interlayer insulating film 9 retreat in a direction away from the source contact trenches 8a may be reduced to about 10 nm or less. Thus, at a subsequent process, coverage of the step (step coverage) by the W film 13a deposited on the front surface of the semiconductor substrate 8 is enhanced.

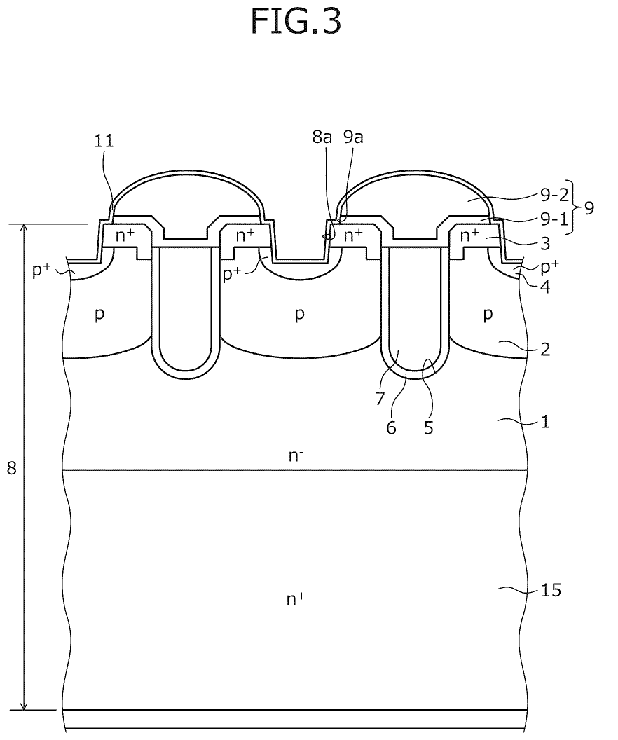

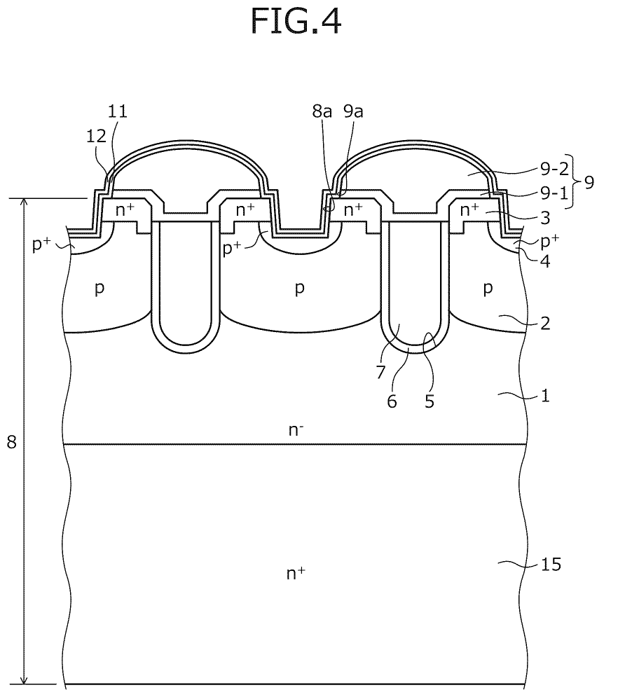

Next, as depicted in FIG. 3, under an atmosphere of a temperature not higher than about 300 degrees C. (for example, about 200 degrees C.), the TiSix film 11 is deposited (formed) along the surface (the top surface and the side surfaces) of the interlayer insulating film 9 and along the inner walls (the bottoms and the sidewalls) of the source contact trenches 8a by sputtering (first deposition process). The thickness of the TiSix film 11 is, for example, about 40 nm. No particular heat treatment such as for converting a Ti film into a silicide is performed and thus, the thickness of the TiSix film 11 at the time of sputtering is maintained and no volumetric expansion occurs. Next, as depicted in FIG. 4, under an atmosphere of a temperature not higher than about 300 degrees C. (for example, about 200 degrees C.), the TiN film 12 is deposited (formed) along the surface of the TiSix film 11 by sputtering (second deposition process).

The TiSix film 11 and the TIN film 12 may be formed using different sputtering devices. Alternatively, for example, the TiSix film 11 and the TIN film 12 may be formed successively using a single sputtering device capable of accommodating multiple sputtering targets and suitably switching the sputtering targets, feed gas, etc. By successively forming the TiSix film 11 and the TiN film 12 using a single sputtering device, the processes may be simplified and costs may be reduced. As for various conditions such as sputtering targets, feed gases, etc. for forming the TiSix film 11 and the TiN film 12, generally employed conditions may be used for each.

Next, as depicted in FIG. 5, the W film 13a is deposited (formed) at the top surface of the semiconductor substrate 8 by CVD using WF₆ gas as a material gas and monosilane (SiH₄) gas or hydrogen (H₂) gas as a source gas, the W film 13a being deposited so as to be embedded in the contact holes 9a and the source contact trenches 8a. At this time, the TiSix film 11 and the TiN film 12, which cover an entire area of the surface of the interlayer insulating film 9, function as a barrier metal. Thus, even when the material gas of the W film 13a passes through the TIN film 12 at a point where the function of the TiN film 12 as a barrier metal has decreased, no chemical reaction occurs that generates fluorine (F) or H₂, which would reduce the adhesion to the interlayer insulating film 9 as in a case where a titanium (Ti) film is used as a barrier metal.

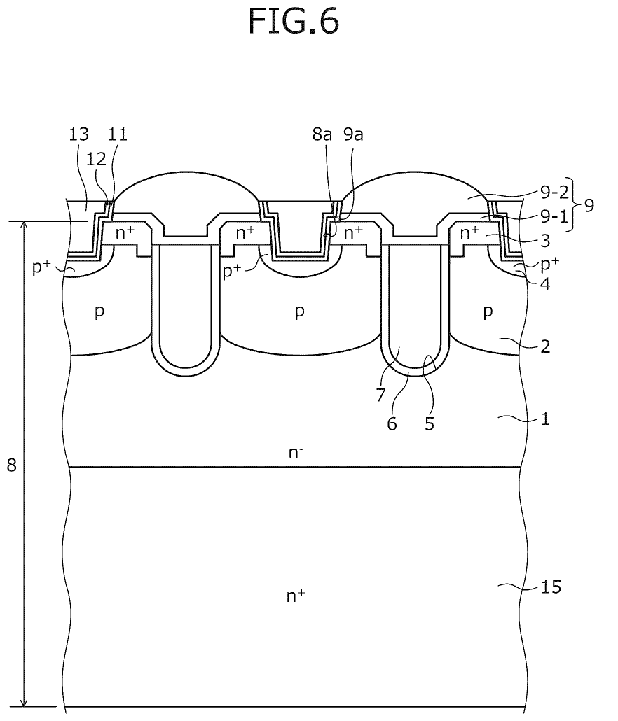

Next, as depicted in FIG. 6, the W film 13a is etched back and the W film 13a is left only in the contact holes 9a and the source contact trenches 8a (third deposition process). Portions of the W film 13a left in the contact holes 9a and the source contact trenches 8a constitute the metal plugs 13. Next, the TIN film 12 and the TiSix film 11 are etched back using the metal plugs 13 as an etching mask, thereby exposing the top surface of the interlayer insulating film (removal process). Dry etching for etching back the W film 13a and dry etching for etching back the TiN film 12 and the TiSix film 11 may be performed successively by switching the etching gas or may be performed using different etching devices.

Next, the front electrode 14 is formed on top of the front surface of the semiconductor substrate 8 by a sputtering and photoetching process (fifth process). Subsequently, a resist mask used to form the front electrode 14 is removed (ashing). Thereafter, for example, crystal damage of the semiconductor substrate 8 is repaired by hydrogen annealing under an atmosphere of a temperature of about 380 degrees C. (first annealing process). While the hydrogen annealing may be performed any time after the front electrode 14 is formed, performing the hydrogen annealing at a timing after the semiconductor substrate 8 is damaged by etching and/or ashing is effective. Thereafter, the n⁺-type drain region 15 and the back electrode 16 are formed at the back surface of the semiconductor substrate 8.

At any timing after the described hydrogen annealing, carrier lifetime control for the n-type drift region 1 may be performed by an exposure to radiation such as irradiation of electron beams (irradiation process) from the front surface or the back surface of the semiconductor substrate 8. Further, after the exposure to radiation, rather than recovering all crystal damage caused by the exposure to radiation, the amount of crystal damage of the semiconductor substrate 8 may be adjusted by performing hydrogen annealing under an atmosphere of a temperature of, for example, about 350 degrees C. so that reverse recovery of parasitic diodes becomes a predetermined lifetime (reverse recovery time) (second annealing process). Crystal damage, which is a factor causing decreases in the gate threshold voltage, may be recovered by the hydrogen annealing after the exposure to radiation. Thus, the semiconductor device 10 depicted in FIG. 1 is completed.

Operation of the semiconductor device 10 according to the first embodiment is described. Voltage that is positive with respect to the source electrode (the front electrode 14) is applied to the drain electrode (the back electrode 16) and pn junctions (main junctions) between the p⁺-type contact regions 4, the p-type base region 2, the n⁻-type drift region 1, and the n⁺-type drain region 15 are reverse biased. In this state, when voltage applied to the gate electrodes 7 is less than the gate threshold voltage, the semiconductor device 10 (MOSFET) maintains an off state.

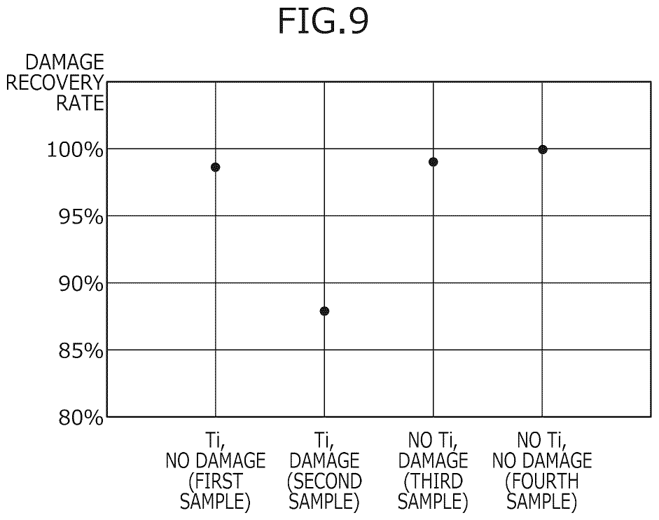

On the interlayer insulating film 9 of the semiconductor device 10, only the front electrode 14 is disposed and the effect of the hydrogen annealing is not inhibited. Thus, even when the semiconductor device 10 is exposed to radiation such as irradiation of electron beams to enhance the switching characteristics of the parasitic diodes, crystal damage recovery of the semiconductor substrate 8 is almost completely achieved by the hydrogen annealing thereafter and gate threshold voltage characteristics are restored (refer to FIG. 9). Thus, the semiconductor device 10 maintains a normally off state.

On the other hand, when voltage that is positive with respect to the source electrode is applied to the drain electrode and voltage that is at least equal to the gate threshold voltage is applied to the gate electrodes 7, a channel (n-type inversion layer) is formed in portions of the p-type base region 2 along the sidewalls of the trenches 5. As a result, a drift current (main current) flows from the n⁺-type drain region 15 through the n-type drift region 1 and the channels to the n+-type source regions 3, whereby the semiconductor device 10 turns on.

As described above, according to the first embodiment, the front electrode and the semiconductor substrate are electrically connected via the TiSix film deposited on the semiconductor substrate by sputtering. The front electrode and the semiconductor substrate are electrically connected via the TiSix film, whereby the contact resistance between the front electrode and the semiconductor substrate may be reduced. Further, according to the first embodiment, in the formation of the TiSix film on the semiconductor substrate, no particular high-temperature treatment of, for example, 600 degrees C. or higher for silicide conversion is necessary and thus, the TiSix film is directly deposited by sputtering under a low-temperature atmosphere of not higher than 300 degrees C., whereby the generation of local stress in the semiconductor substrate may be suppressed.

Further, for example, in an instance in which the TiSix film is formed by a silicide generating reaction with semiconductor substrate, the Ti film, which is the material film for the TiSix film covers the entire surface of the interlayer insulating film. Thus, the effect of the hydrogen annealing for crystal damage recovery of the semiconductor substrate is inhibited or to obtain the effect of the hydrogen annealing, portions of the Ti film covering the top surface of the interlayer insulating film have to be removed. Whereas, according to the first embodiment, the TiSix film is directly deposited by sputtering and thus, no Ti film is formed on the surface of the interlayer insulating film, whereby crystal damage recovery of the semiconductor substrate by the hydrogen annealing is facilitated. For example, even for a product (semiconductor device) for which exposure to radiation such as irradiation of electron beams is performed to enhance switching characteristics such as the reverse recovery time of the body diodes, crystal damage recovery of the semiconductor substrate may be sufficiently achieved by the hydrogen annealing.

In other words, according to the first embodiment, while crystal damage of the semiconductor substrate is assumed to reduce the gate threshold voltage, setting the gate threshold voltage to be higher in advance such as by excessively increasing the doping amount of a predetermined diffused region in the semiconductor substrate in anticipation of the reduction due to the crystal damage of the semiconductor substrate is unnecessary. Thus, in a reliability test such as a high-temperature application test, variation of characteristics does not easily occur and reliability (reliability of various characteristics by reliability tests such as a high-temperature application test) of the product is enhanced. Further, according to the first embodiment, no Ti film is used as a barrier metal and thus, during formation of the metal plugs, problems (refer to later-described comparison example) caused by the material gas and the Ti film reacting with each other do not occur. Therefore, decreased adhesion with the interlayer insulating film may be prevented.

Further, for example, in an instance in which a CVD method is used to deposit the TiSix film and the TiN film, conditions such as gas species used to form the TiSix film and the TiN film, respectively, differ and thus, the TiSix film and the TiN film cannot be successively formed using the same CVD equipment. On the other hand, according to the first embodiment, the TiSix film is deposited by sputtering and thus, the TiSix film and the TiN film may be formed successively using the same sputtering device. As a result, processes may be simplified, whereby costs may be reduced. Further, between the formation of the TiSix film and the formation of the TiN film, a step of conveying the semiconductor wafer may be omitted and thus, contamination during transport of the semiconductor wafer is suppressed, whereby yield and reliability of the product is enhanced.

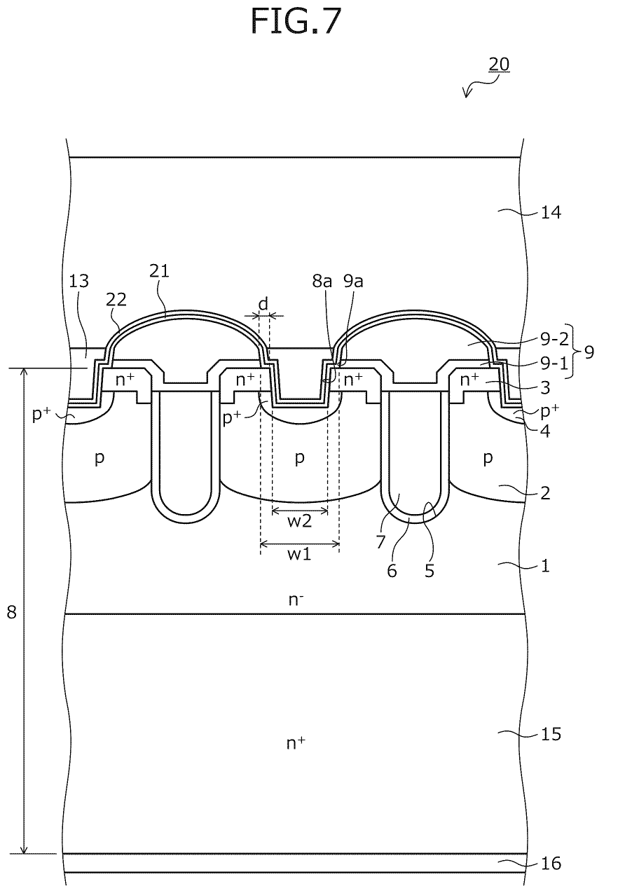

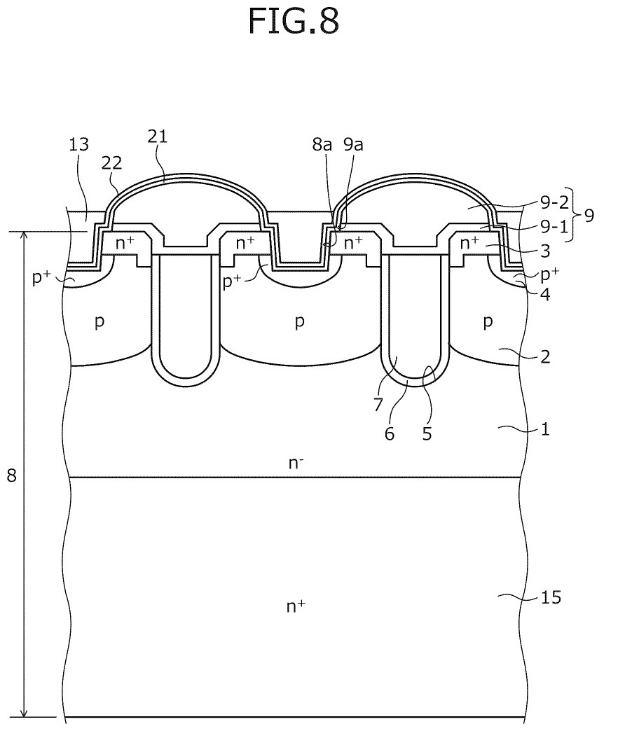

A semiconductor device according to a second embodiment that solves the problems above is described. FIG. 7 is a cross-sectional view depicting a structure of the semiconductor device according to the second embodiment. FIG. 8 is a cross-sectional view depicting a state of the semiconductor device according to the second embodiment during manufacture. A semiconductor device 20 according to the second embodiment differs from the semiconductor device 10 according to the first embodiment (refer to FIG. 1) in that a TiSix film 21 and a TiN film 22 configuring the contact structure of the front electrode 14 extend between the front electrode 14 and the interlayer insulating film 9 and cover the entire surface of the interlayer insulating film 9.

Configuration of the TiSix film 21 and configuration of the TIN film 22 inside the contact holes 9a and the source contact trenches 8a are the same as the configuration of the TiSix film 11 and the configuration of the TiN film 12 in the first embodiment, respectively. The TiSix film 21 and the TiN film 22 function as a barrier metal that suppresses the diffusion of metal atoms from the front electrode 14 to the interlayer insulating film 9. The TiSix film 21 and the TiN film 22 have a function of suppressing damage to the interlayer insulating film 9 caused by ultrasonic vibration during wire bonding to the front electrode 14.

A method of manufacturing the semiconductor device 20 according to the second embodiment is implemented by the method of manufacturing the semiconductor device 10 according to the first embodiment in which etching back of the TiSix film 11 and the TiN film 12 (refer to FIG. 6) is omitted. In other words, similar to the first embodiment, the processes of forming the trench gate structure to forming the metal plugs 13 are sequentially performed (FIGS. 2 to 5, 8). Thereafter, the TiSix film 11 and the TiN film 12 are left as they are on the top surface of the interlayer insulating film 9 (FIG. 8) and the process of forming the front electrode 14 and subsequent processes are sequentially performed, thereby completing the semiconductor device 20 depicted in FIG. 7.

Even when the TiSix film 11 and the TiN film 12 are left as they are on the top surface of the interlayer insulating film 9, the effect of the hydrogen annealing for crystal damage recovery of the semiconductor substrate 8 is not inhibited. Further, the TiSix film 21 has higher adhesion with the interlayer insulating film 9 as compared to the TiN film 22 and the front electrode 14. Thus, adhesion of the front electrode 14 is enhanced by the TiSix film 21. Further, the process for removing portions of the TiSix film 11 and the TiN film 12 may be omitted, enabling reductions in the number of processes and generation of particles.

As described, according to the second embodiment, even when the top surface of the interlayer insulating film is covered by the TiSix film and the TiN film, effects similar to the first embodiment may be obtained. According to the second embodiment, the number of processes and the generation of particles are reduced, whereby yield may be increased and costs may be reduced.

A relationship between crystal damage recovery of the semiconductor substrate by hydrogen annealing and a barrier metal was verified. FIG. 9 is a figure depicting a relationship between crystal damage recovery of the semiconductor substrate by hydrogen annealing and a barrier metal. Crystal damage recovery of the semiconductor substrate by hydrogen annealing was verified with respect to MOSFETs having a general trench gate structure (hereinafter, experimental examples), using four samples (hereinafter, first to fourth samples) with different conditions (barrier metal, no barrier metal, crystal damage of the semiconductor substrate, no crystal damage thereof), the results are depicted in FIG. 9. The first sample has a Ti film as a barrier metal on the interlayer insulating film and is free of crystal damage in the semiconductor substrate due to exposure to radiation (Ti, no damage). The second sample has a Ti film as a barrier metal on the interlayer insulating film and has crystal damage in the semiconductor substrate due exposure to radiation (Ti, damage). The third sample is free of a barrier metal and has crystal damage in the semiconductor substrate due to exposure to radiation (no Ti, damage). The fourth sample is free of a barrier metal and free of crystal damage in the semiconductor substrate due to exposure to radiation (no Ti, no damage).

In FIG. 9, “damage recovery rate” indicates whether the gate threshold voltage after crystal damage recovery of the semiconductor substrate by the hydrogen annealing recovers to the design value of the gate threshold voltage and assumes the crystal damage recovery of the semiconductor substrate by hydrogen annealing in the fourth sample as a reference (=100%). In FIG. 9, “damage”, “no damage” indicates whether crystal damage due to exposure to radiation is present or absent and the first to fourth samples were subjected to the hydrogen annealing in a state in which crystal damage similarly occurred in the semiconductor substrate during other manufacturing processes (for example, ion implantation).

As depicted in FIG. 9, from the results for the second sample, it was confirmed that due to the presence of the Ti film as a barrier metal, crystal damage of the semiconductor substrate due to exposure to radiation could not be sufficiently recovered. Further, from the results for the third sample, it was confirmed that due to the absence of a Ti film as a barrier metal, crystal damage of the semiconductor substrate due to exposure to radiation could be recovered to a same extent as the first and fourth samples that are free of crystal damage due to exposure to radiation. Further, the damage recovery rate for the third sample is higher than the damage recovery rate for the first sample, thus, it was found that due to the absence of a Ti film as a barrier metal, the recovery rate for crystal damage in the semiconductor substrate occurring in processes other than those for radiation exposure also increases.

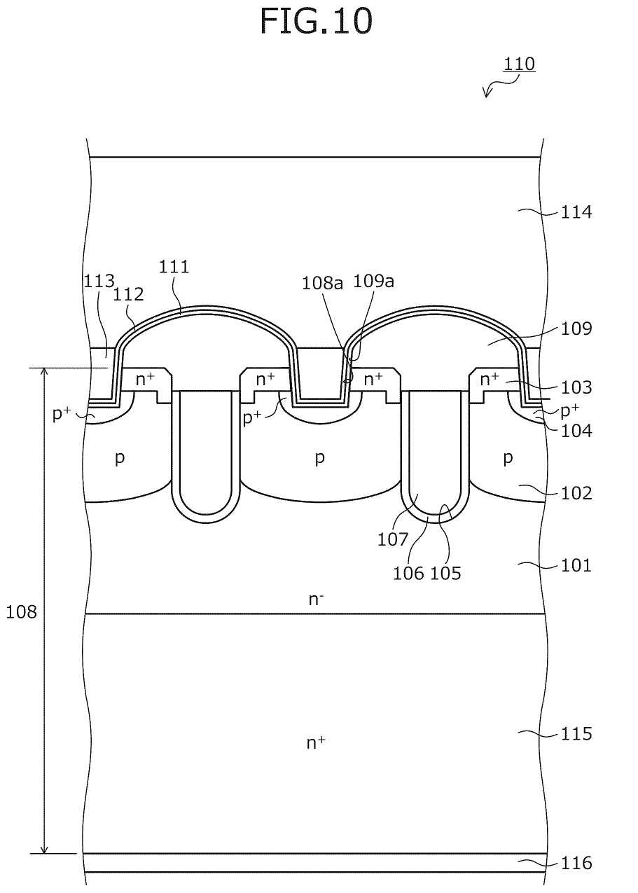

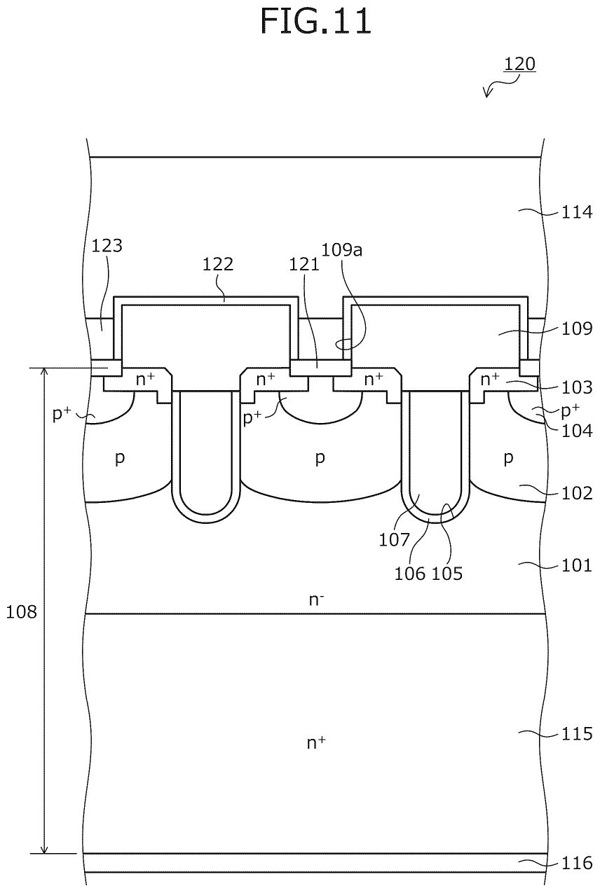

As comparison examples, a MOSFET is described in which the contact resistance between the front electrode and the semiconductor substrate is reduced by providing a metal film with a high hardness and a high melting point such as Ti or (Ni), a titanium silicide (TiSi) film formed by converting a Ti film into a silicide, etc. between the front electrode and the semiconductor substrate. FIGS. 10 and 11 are cross-sectional views depicting a structure of first and second comparison examples. Semiconductor devices 110, 120 (hereinafter, the first and second comparison examples) depicted in FIGS. 10 and 11 are vertical MOSFETs with a general trench gate structure and have respectively different contact structures between a front electrode 114 and a semiconductor substrate 108.

In the first and second comparison examples, the trench gate structure is configured by a p-type base region 102, n⁺-type source regions 103, p⁺-type contact regions 104, trenches 105, gate insulating films 106, and gate electrodes 107 and is provided between a front surface of the semiconductor substrate 108 and an n⁻-type drift region 101. An interlayer insulating film 109 is provided on the front surface of the semiconductor substrate 108 and covers the gate electrodes 107. An n⁺-type drain region 115 is provided between a back surface of the semiconductor substrate 108 and the n-type drift region 101. A back electrode 116 constituting a drain electrode is provided at the back surface of the semiconductor substrate 108 and is in contact with the n⁺-type drain region 115.

The first comparison example (the semiconductor device 110 depicted in FIG. 10) has source contact trenches 108a that are continuous with contact holes 109a of the interlayer insulating film 109, the source contact trenches 108a being provided in the semiconductor substrate 108, at the front surface of the semiconductor substrate 108. The n⁺-type source regions 103 and the p⁺-type contact regions 104 are exposed at inner walls of the source contact trenches 108a. Along sidewalls (side surfaces of the interlayer insulating film 109) of the contact holes 109a and inner walls of the source contact trenches 108a, a metal film 111 having a high hardness and a high melting point such as Ti or Ni and a TiN film 112 are sequentially formed by sputtering.

The metal film 111 and the TiN film 112 extend onto a top surface of the interlayer insulating film 109 and cover the entire top surface of the interlayer insulating film 109. W plugs 113 are embedded in the contact holes 109a and the source contact trenches 108a so as to be provided on the TiN film 112. The front electrode 114 is provided on the TiN film 112 and the W plugs 113. The front electrode 114 is electrically connected to the n⁺-type source regions 103 and the p⁺-type contact regions 104 via the W plugs 113, the TIN film 112, and the metal film 111 and functions as a source electrode.

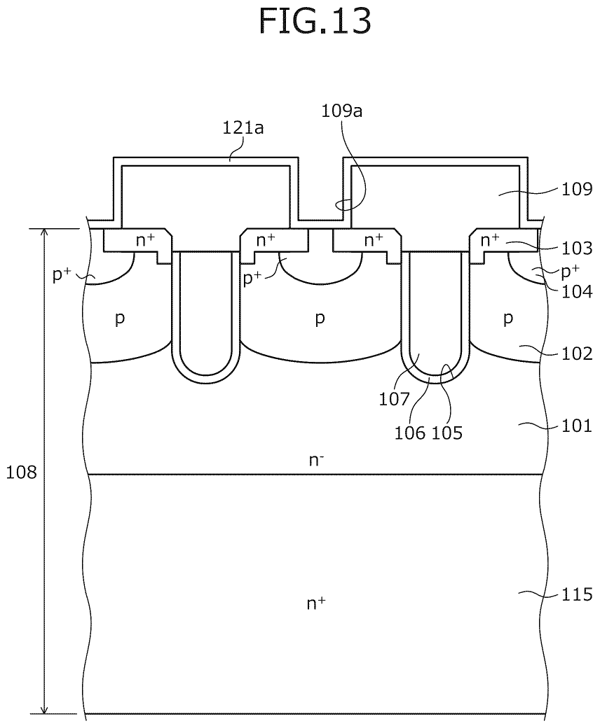

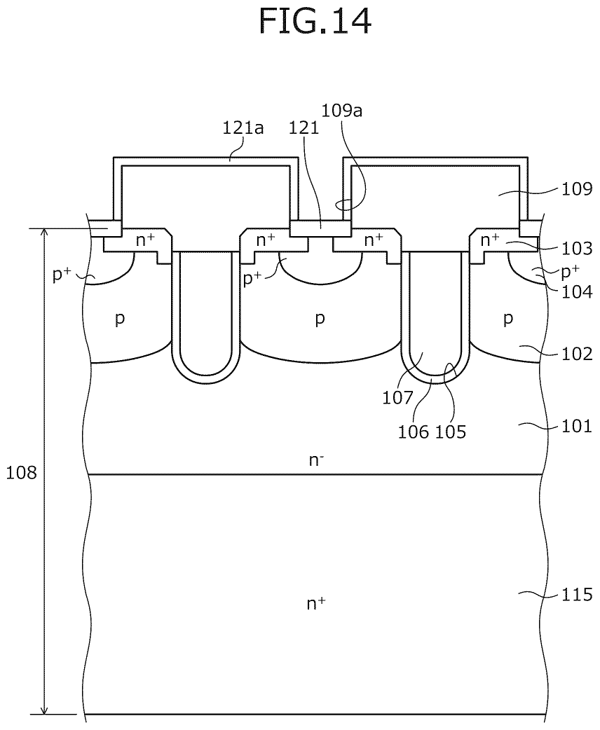

The second comparison example (the semiconductor device 120 depicted in FIG. 11) differs from the first comparison example in that instead of the metal film 111, only a TiSi film 121 is provided on an Si portion. The second comparison example is free of the source contact trenches 108a and thus, has a structure in which a thickness of the interlayer insulating film 109 is left thicker as compared to in the first comparison example. The TiSi film 121 is formed by a silicide reaction between Ti atoms in a Ti film (later-described Ti film 121a, refer to FIGS. 13 and 14) and Si atoms in the semiconductor substrate 108 and is only provided on the Si portions (i.e., portions of the front surface of the semiconductor substrate 108) in the contact holes 109a of the interlayer insulating film 109.

The TiSi film 121 is not provided on the surface of the interlayer insulating film 109. A thickness of the TiSi film 121 is, for example, about 60 nm and in the depth direction from the front surface of the semiconductor substrate 108, the TiSi film 121 terminates at a position closer to the front surface of the semiconductor substate than are portions where the n⁺-type source regions 103 terminate in the depth direction. While not depicted, even in an instance in which the second comparison example has the source contact trenches 108a, the TiSi film 121 is provided only on Si portions (i.e., inner walls of the source contact trenches 108a). The TiN film 122 is provided along the surface of the TiSi film 121 and the surface of the interlayer insulating film 109. W plugs 123 are embedded in the contact holes 109a so as to be on the TIN film 122.

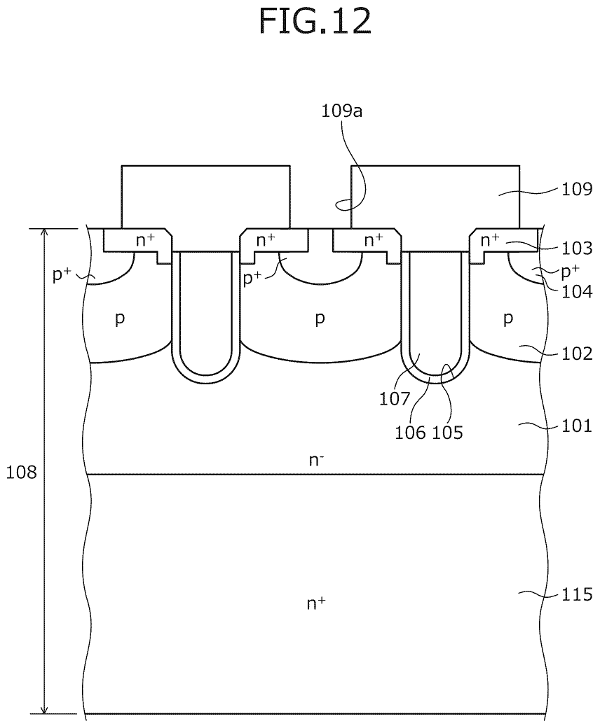

A method of manufacturing the second comparison example (the semiconductor device 120 depicted in FIG. 11) is described. FIGS. 12, 13, 14, 15, 16, 17, and 18 are cross-sectional views depicting states of the second comparison example during manufacture. First, as depicted in FIG. 12, by a general method, in the semiconductor substrate 108, at the front surface thereof, the trench gate structure constituted by the p-type base region 102, the n⁺-type source regions 103, the p⁺-type contact regions 104, the trenches 105, the gate insulating films 106, and the gate electrodes 107 is formed. Next, the interlayer insulating film 109 is formed in an entire area of the front surface of the semiconductor substrate 108. Next, the contact holes 109a that penetrate through the interlayer insulating film 109 in the depth direction and reach the semiconductor substrate 108 are formed.

Next, as depicted in FIG. 13, the Ti film 121a having a thickness of, for example, about 40 nm is formed along the surface of the interlayer insulating film 109 and the surface of portions of the semiconductor substrate 108 exposed in the contact holes 109a, by sputtering under an atmosphere of a temperature of about 300 degrees C. Next, as depicting in FIG. 14, the Ti film 121a and the semiconductor substrate 108 are caused to react with each other and form a silicide by a rapid thermal annealing (RTA) treatment at a temperature of, for example, about 600 degrees C., thereby forming the TiSi film 121 on portions of the front surface of the semiconductor substrate 108 in the contact holes 109a, Due to the volumetric expansion caused by the silicide conversion, the thickness of the TiSi film 121 increases to about 60 nm.

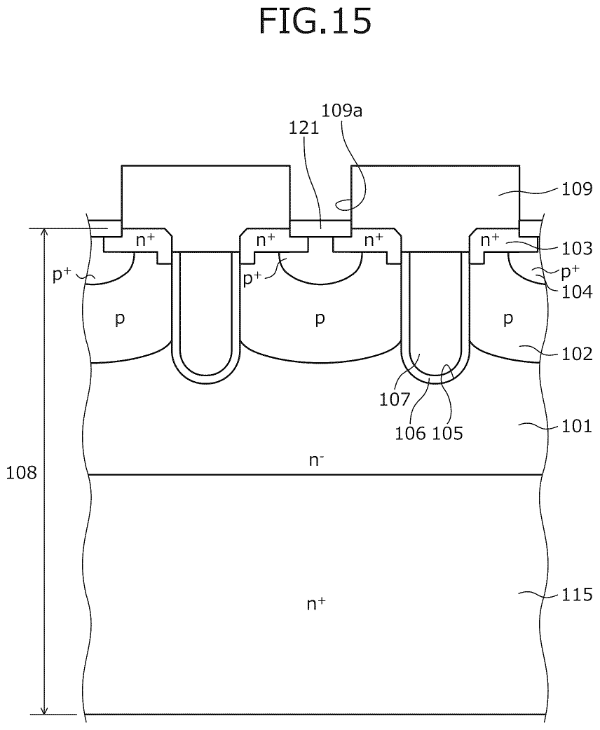

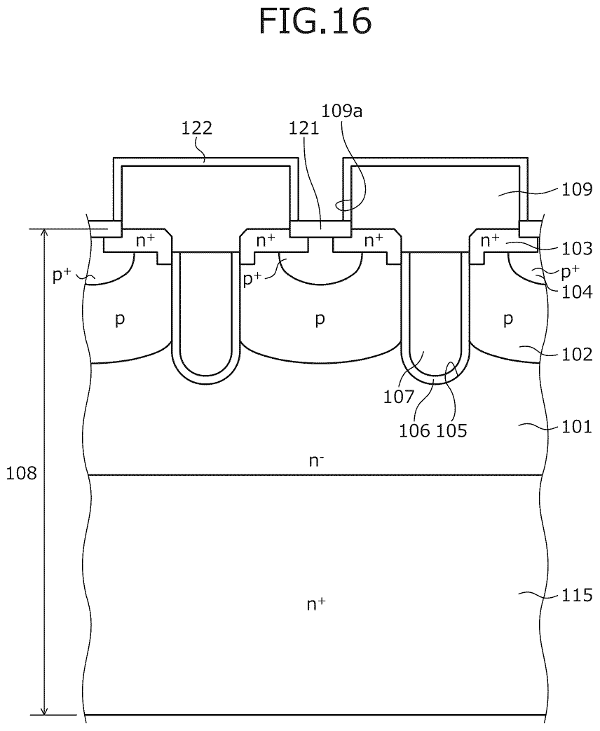

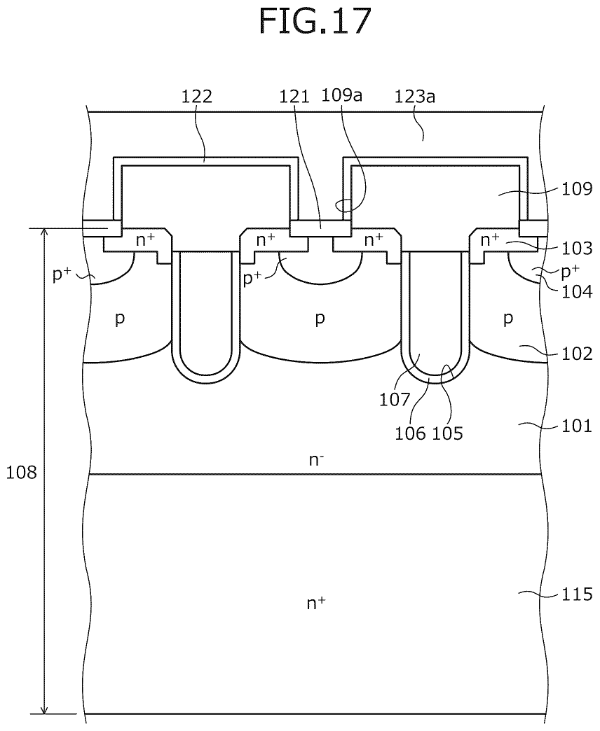

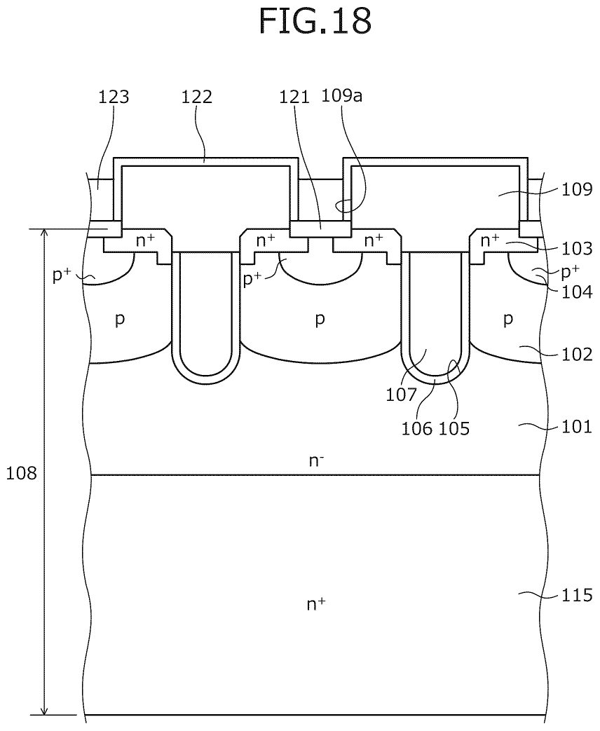

Next, as depicted in FIG. 15, portions of the Ti film 121a remaining unreacted on the surface of the interlayer insulating film 109 are removed. Next, as depicted in FIG. 16, the TiN film 122 is formed along the surface of the TiSi film 121 and the surface of the interlayer insulating film 109 by sputtering. Next, as depicted in FIG. 17, a W film 123a is formed by CVD on a top surface of the front surface of the semiconductor substrate 108 so as to be embedded in the contact holes 109a. Next, as depicted in FIG. 18, the W film 123a is etched back, thereby leaving portions thereof constituting the W plugs 123 only in the contact holes 109a.

Next, the front electrode 114 is formed on the top surface of the semiconductor substrate 108. The n⁺-type drain region 115 and the back electrode 116 are formed at the back surface of the semiconductor substrate 108. Next, carrier lifetime of the n-type drift region 101 is controlled by exposure to radiation such as irradiation of electron beams. Crystal damage occurs in the semiconductor substrate 108 in the processes up to here (particularly during the exposure to radiation for controlling the carrier lifetime of the n-type drift region 101) whereby various characteristics such as the gate threshold voltage vary. Thus, next, the crystal damage of the semiconductor substrate 8 is recovered by the hydrogen annealing, whereby the second comparison example is completed.

In the first comparison example described above, a contact structure with two layers including a Ti film and a TiN film or with three layers including a Ti film, a TiN film, and a Ti film, not only a single Ti film (the metal film 111), is commonly known. A Ti film has low contact resistance with an n-type Si (the semiconductor substrate 108). Thus, in the first comparison example, even when the width of the contact holes 109a is reduced for reductions in device size, increases in the contact resistance between the front electrode 114 and the semiconductor substrate 108 may be suppressed. However, in the first comparison example, when the metal film 111 between the front electrode 114 and the interlayer insulating film 109 is a Ti film, the Ti film inhibits the effect of the hydrogen annealing.

Further, in the first comparison example, WF₆ gas, which is the material gas for the W plugs 113 may pass through the TiN film 12 and come into contact with the Ti film. When the WF₆ gas and the Ti film come into contact, fluorine and H₂, which reduce adhesion with the interlayer insulating film 109, are generated. Further, a portion of the Ti film disappears and the TIN film 112 constituting an upper layer lifts and cracks. As a result, adhesion of the front electrode 114 decreases. For example, while an Ni film may be used as the metal film 111 instead of the Ti film or a portion of the Ti film covering the surface of the interlayer insulating film 109 may be removed to solve the problems above, a function of the metal film 111 as a barrier metal may decreases as a result.

Further, when the portion of the Ti film (the metal film 111) covering the surface of the interlayer insulating film 109 is removed, ultrasonic vibration during wire bonding to the front electrode 114 damages the interlayer insulating film 109. Further, as a result of removing the portion of the Ti film covering the surface of the interlayer insulating film 109, costs increases due to an increase in the number of processes and a decrease in yield accompanying the generation of particles. Further, when the portions of the Ti film covering the surface of the interlayer insulating film 109 are removed, the TIN film 112, which has lower adhesion with the interlayer insulating film 109 than does the Ti film, is in contact with the interlayer insulating film 109 and thus, adhesion between the interlayer insulating film 109 and the front electrode 114 decreases.

In the second comparison example, remaining portions of the Ti film 121a, which is a material of the TiSi film 121 (refer to FIG. 15), are removed and thus, similar to the first comparison example, the number of processes and the generation of particles increase, whereby yield decreases. When the remaining portions of the Ti film 121a are not removed and left on the interlayer insulating film 109, problems similar to those of the first comparison example occur during the formation of the W plugs 123 and during the hydrogen annealing. Further, in the second comparison example, while the contact resistance between the TiSi film 121 and the semiconductor substrate 108 is reduced, the thickness of the TiSi film 121 becomes thicker than the thickness at the time of deposition of the Ti film 121a due to volumetric expansion caused by the silicide conversion, and the greater the thickness increases, the greater is the stress generated locally in the semiconductor substrate 108.

Further, in the first and second comparison examples, in an instance in which it is assumed that crystal damage in the semiconductor substrate 108 will not be sufficiently recovered by the hydrogen annealing and a predetermined characteristic of the product is preset to be higher by excessively increasing the doping amount of a predetermined region in the semiconductor substrate 108 in anticipation of the amount of decrease due to the crystal damage of the semiconductor substrate 108, the predetermined characteristic may be higher than a predetermined value by recovering the crystal damage of the semiconductor substrate 108 by the hydrogen annealing. Thus, in a reliability test such as a high-temperature application test, variation of the characteristic easily occurs, adversely affecting the reliability of the product (the semiconductor devices 110, 120).

For example, in Japanese Laid-Open Patent Publication No. H7-297136, a polycrystalline silicon (poly-Si) film deposited on a semiconductor substrate is caused to react with titanium radicals generated under a heated state of about 500 degrees C. for conversion into a silicide, thereby forming a TiSi film. Thus, similar to the second comparison example, stress locally generated in the semiconductor substrate due to the volumetric expansion of the TiSi film caused by the conversion into a silicide increases. Further, in an instance in which the conversion of the polycrystalline silicon film into a silicide does not reach the semiconductor substrate in the depth direction from the top surface of the polycrystalline silicon film, the contact resistance with the semiconductor substrate increases. Further, a Ti film is included in the metal wiring and thus, similar to the first comparison example, the effect of the hydrogen annealing is inhibited.

For example, in Japanese Laid-Open Patent Publication No. 2015-124397, while a TiSi film is directly formed on a semiconductor substrate by PECVD, when chlorine (Cl) contained in the feed gas composition of the PECVD diffuses into the semiconductor substrate or becomes mixed in as a residue in the TiSi film or the semiconductor substrate, corrosion of the TiSi film or semiconductor substrate may result. Further, when a deposited film is formed using a material gas under a plasma state, stress is high and the resistance value increases. To lower the resistance value of the deposited film, for example, it is assumed that the sheet resistance has to be reduced by making the thickness of the deposited film uniform across the surface by a heat treatment and thus, the number of processes increases.

Further, in Japanese Laid-Open Patent Publication No. 2015-124397, when a Ti film is deposited by PECVD after an Si film is deposited on a semiconductor substrate by CVD, the Si film and the Ti film are caused to reach with each other; however, while a TiSi film is formed, it is difficult to form an Si film by a method other than crystal growth by a chemical reaction between a feed gas and the semiconductor substrate (Si substrate). Even when it is assumed that an Si film is formed by CVD, thereafter, when the Si film and the Ti film formed in an entire area of the top surface of the semiconductor substrate including the surface of the Si film are caused to react with each other, stress of the TiSi film increases due to volumetric expansion. Further, portions of the Ti film remaining unreacted inhibit the effect of the hydrogen annealing, similar to the first comparison example.

On the other hand, according to the first and second embodiments (refer to FIGS. 1 and 7), the metal film functioning as a barrier metal and provided in at least a portion of the surface of the interlayer insulating film 9 is constituted by the TiSix films 11, 21 and the TIN films 12, 22 and no Ti film is provided. Thus, the effect of the hydrogen annealing is not inhibited and decreased adhesion with the interlayer insulating film 9 caused by contact between the material gas of the metal plugs 13, 23 and the metal film functioning as a barrier metal does not occur. Further, the TiSix films 11, 21 are formed by sputtering under a low-temperature atmosphere of not more than about 300 degrees C. and stress that occurs locally in the semiconductor substrate 8 may be suppressed. Thus, the reliability of the product is enhanced.

Further, according to the second embodiment (refer to FIG. 7), the entire surface of the interlayer insulating film 9 is covered by the TiSix film 21 and the TiN film 22 and thus, an effect thereof as a barrier metal is enhanced. Further, the TiSix film 21 and the TiN film 22 may suppress damage of the interlayer insulating film 9 caused by ultrasonic vibration during wire bonding to the front electrode 14. Further, according to the second embodiment, the TiSix film 21 and the TIN film 22 are not selectively removed and thus, the number of processes is reduced and generation of particles is reduced, whereby yield is enhanced and cost may be reduced.

Further, in Japanese Laid-Open Patent Publication No. H10-321812, Japanese Laid-Open Patent Publication No. H10-79431, Japanese Laid-Open Patent Publication No. H10-79481, and Japanese Laid-Open Patent Publication No. H7-297136, the TiSiN film included in a stacked structure of the front electrode is different from the TiSix films 11, 21 of the first and second embodiments and inhibits the effect of the hydrogen annealing for recovering crystal damage of the semiconductor substrate. Further, in Japanese Laid-Open Patent Publication No. H10-321812, after a TiSiN layer is formed by sputtering after formation of a Ti film, an oxidation or heat treatment is performed oxidizing an upper portion of the surface of the TiSiN layer, whereby a titanium-silicon-nitride oxide layer constituting an oxide layer of the TiSiN layer is formed, thereby forming a capacitor constituted by these stacked layers, which differs from forming a contact with a semiconductor substrate like that of the first and second embodiments. Further, in Japanese Laid-Open Patent Publication No. H10-321812, a high-temperature heat treatment of exceeding 600 degrees C. is performed and thus, stress locally generated in the semiconductor substrate due to volumetric expansion caused by alloying increases.

In Japanese Laid-Open Patent Publication No. H10-79431, a TiSiN layer is formed between a semiconductor substrate and an interlayer insulating film, which differs from the structure of the TiSix films 11, 21 of the first and second embodiments. Further, a high-temperature heat treatment is performed and thus, stress locally generated in the semiconductor substrate due to volumetric expansion caused by alloying increases. In Japanese Laid-Open Patent Publication No. H10-79481, a structure includes, at a surface of a semiconductor substrate, a first conductive layer containing Si, a second conductive layer such as a TiSiN layer formed on the first conductive layer and containing nitrogen, Si, and a metal with a high melting point, and a third conductive layer formed on the second conductive layer and containing a platinum-group element; the first, second, and third conductive layers are connected to each other; and mutual diffusion of the Si and platinum-group element is prevented even when a high-temperature heat treatment is performed and thus, differs from forming a contact with a semiconductor substrate like that of the first and second embodiments. Further, in Japanese Laid-Open Patent Publication No. H10-79481, a high-temperature heat treatment is performed and thus, stress locally generated in the semiconductor substrate due to volumetric expansion caused by alloying increases.

In Japanese Laid-Open Patent Publication No. H7-297136, a contact hole with a high aspect ratio reaching a semiconductor substrate is formed in the interlayer insulating film; a polycrystalline or amorphous Si film having a thickness such that said film does not completely occupy the contact hole is stacked on the surface of the interlayer insulating film, including the sides and the bottom (semiconductor substrate surface) of the contact hole; the Si film is converted to a TiSi film while a Ti film is deposited by PECVD; and a TiN film is further formed on the surface of the Ti film, which differs from the method of forming the TiSix films 11 and 21 in the first and second embodiments. The stacking of a polycrystalline or amorphous Si film further differs from the first and second embodiments. Further, in Japanese Laid-Open Patent Publication No. H7-297136, stress locally generated in the semiconductor substrate due to the volumetric expansion of the TiSi film caused by the conversion into a silicide under a high-temperature plasma increases and plasma damage may remain.

In a first example of a method of forming a contact layer in Japanese Laid-Open Patent Publication No. 2015-124397, a contact hole with a high aspect ratio reaching a semiconductor substrate is formed in the interlayer insulating film; a TiSi film having a thickness such that said film does not completely occupy the contact hole is stacked thereon by PECVD; and differs from the method of forming the TiSix films 11, 21 of the first and second embodiments. Further, in Japanese Laid-Open Patent Publication No. 2015-124397, chlorine (Cl) contained in a feed gas composition of the PECVD for forming the TiSi film is a factor causing corrosion, reduced reliability, and variation of characteristics of the semiconductor substrate. Further, plasma damage may remain. Moreover, in the first example of the method of forming the contact layer in Japanese Laid-Open Patent Publication No. 2015-124397, when a heat treatment of a temperature higher than a temperature for forming the TiSi film is performed after the TiSi film is formed, stress locally generated in the semiconductor substrate increases.

In a second example of the method of forming the contact layer in Japanese Laid-Open Patent Publication No. 2015-124397, a contact hole with a high aspect ratio reaching a semiconductor substrate is formed in the interlayer insulating film; an Si film having a thickness such that said film does not completely occupy the contact hole is formed by low pressure CVD (LPCVD); while a Ti film is formed by PECVD, the Ti film is caused to react with the Si film to be converted into the TiSi film and differs from the TiSix films 11, 21 of the first and second embodiments. Further, in the second example of the method of forming the contact layer in Japanese Laid-Open Patent Publication No. 2015-124397, when CI of a TiCI gas used remains, characteristics vary, reliability decreases, and plasm damage may remain. Further, silicide conversion is performed under a plasma environment and thus, stress locally generated in the semiconductor substrate due to volumetric expansion of the TiSi film increases.

In Japanese Patent No. 3988342, a polysilicon film is formed as a gate electrode to reduce gate resistance; a TiSi film is formed on the polysilicon film by PVD; side etching of the TiSi film is large and thus, an oxide film is formed at a side surface of a gate electrode to prevent narrowing of a gate width; and no contact structure of the front electrode is disclosed, which differs from the first and second embodiments, in which a contact of the semiconductor substrate is formed. Further, in Japanese Patent No. 3988342, a high-temperature heat treatment is performed and thus, stress locally generated in the semiconductor substrate due to volumetric expansion caused by alloying increases.

In contrast, in the first and second embodiments, the TiSix film is deposited on the semiconductor substrate by sputtering as described above and thus, the problems of Japanese Laid-Open Patent Publication No. H10-321812, Japanese Laid-Open Patent Publication No. H10-79431, Japanese Laid-Open Patent Publication No. H10-79481, Japanese Laid-Open Patent Publication No. H7-297136, Japanese Laid-Open Patent Publication No. 2015-124397, and Japanese Patent No. 3988342 do not occur.

In the foregoing, the present disclosure is not limited to the embodiments described above and various modifications within a range not departing from the spirit of the disclosure are possible. For example, the embodiments above are not limited to MOSFETs with a trench gate structure and are applicable to various semiconductor devices with a configuration in which a front electrode contact structure is in ohmic contact with a semiconductor substrate in a contact hole of an interlayer insulating film. Further, in the embodiments, while a first conductivity type is assumed to be an n-type and a second conductivity type is assumed to be a p-type, the present disclosure is similarly implemented with the first conductivity type is a p-type and the second conductivity type is an n-type.

The semiconductor device and the method of manufacturing a semiconductor device according to the present disclosure achieve an effect in that reliability may be enhanced.

As described, the semiconductor device and the method of manufacturing a semiconductor device according to the present disclosure are useful for power semiconductor devices used in power converting equipment, power source devices of various types of industrial machines, etc. and are particularly suitable for semiconductor devices for which size reductions are implemented by contact trenches.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate having a first main surface and a second main surface opposite to each other;
a first semiconductor region of a first conductivity type, provided in the semiconductor substrate;
a second semiconductor region of a second conductivity type, provided between the first main surface of the semiconductor substrate and the first semiconductor region;
a device structure provided in the semiconductor substrate, at the first main surface thereof, the device structure having a pn junction between the second semiconductor region and the first semiconductor region;
an interlayer insulating film provided at the first main surface of the semiconductor substrate, the interlayer insulating film covering the device structure;
a contact hole penetrating through the interlayer insulating film in a depth direction and reaching the semiconductor substrate;
a contact structure in contact with the semiconductor substrate in the contact hole;
a first electrode electrically connected to the second semiconductor region via the contact structure; and
a second electrode provided at the second main surface of the semiconductor substrate, wherein
the contact structure is configured by:
a titanium silicide film in contact with the semiconductor substrate in the contact hole, the titanium silicide film extending along a surface of the interlayer insulating film including portions thereof along sidewalls of the contact hole,
a titanium nitride film provided along a surface of the titanium silicide film, and a metal plug embedded in the contact hole, onto the titanium nitride film.

2. The semiconductor device according to claim 1, further comprising a contact trench of a predetermined depth, provided in the semiconductor substrate, at the first main surface, the contact trench being continuous with the contact hole, wherein
the titanium silicide film is provided along the sidewalls of the contact hole and an inner wall of the contact trench.

3. The semiconductor device according to claim 2, wherein the titanium silicide film has a thickness that is uniform from the sidewalls of the contact hole to sidewalls of the contact trench.

4. The semiconductor device according to claim 2, wherein the interlayer insulating film is positioned not more than 10 nm from the contact trench in a direction parallel to the first main surface of the semiconductor substrate.

5. The semiconductor device according to claim 1, wherein
the titanium silicide film terminates at a side surface of the interlayer insulating film, and
the first electrode is provided on a top surface of the interlayer insulating film, the first electrode being in contact with the interlayer insulating film.

6. The semiconductor device according to claim 1, wherein
the titanium silicide film covers an entire area of the surface of the interlayer insulating film in the contact hole, and
the first electrode is provided on a top surface of the interlayer insulating film via the titanium silicide film and the titanium nitride film.

7. The semiconductor device according to claim 1, wherein the titanium silicide film is a deposited film.

8. A method of manufacturing a semiconductor device, the method comprising:
preparing a semiconductor substrate having a first semiconductor region of a first conductivity type therein, the semiconductor substrate having a first main surface and a second main surface opposite to each other;
as a first process, forming, in the semiconductor substrate, at the first main surface thereof, a second semiconductor region of a second conductivity type, the second semiconductor region being in contact with the first semiconductor region, thereby forming a device structure having a pn junction between the second semiconductor region and the first semiconductor region;
as a second process, forming, at the first main surface of the semiconductor substrate, an interlayer insulating film covering the device structure;
as a third process, forming a contact hole penetrating through the interlayer insulating film in the depth direction and reaching the semiconductor substrate;
as a fourth process, forming a contact structure in contact with the semiconductor substrate in the contact hole;
as a fifth process, forming a first electrode electrically connected to the second semiconductor region via the contact structure; and
as a first annealing process, performing a heat treatment under a hydrogen atmosphere after forming the first electrode in the fifth process and thereby recovering crystal damage of the semiconductor substrate, wherein
the forming the contact structure in the fourth process includes:
as a first deposition process, performing a first sputtering and thereby depositing a titanium silicide film covering an entire area of a surface of the interlayer insulating film, the titanium silicide film being in contact with the semiconductor substrate in the contact hole,
as a second deposition process, performing a second sputtering and thereby depositing a titanium nitride film on a surface of the titanium silicide film, and
as a third deposition process, embedding a metal plug in the contact hole, onto the titanium nitride film, and
the contact structure includes the titanium silicide film, the titanium nitride film, and the metal plug.

9. The method of manufacturing according to claim 8, further comprising, as a sixth process after the forming the contact hole in the third process but before the forming the contact structure in the fourth process, forming, in the semiconductor substrate, at the first main surface thereof, a contact trench of a predetermined depth, the contact trench being continuous with the contact hole, wherein
in the first deposition process, the titanium silicide film is formed along the surface of the interlayer insulating film and an inner wall of the contact trench.

10. The method of manufacturing according to claim 9, further comprising, as a seventh process after the forming the contact trench in the sixth process but before the forming the contact structure in the fourth process, flattening the interlayer insulating film.

11. The method of manufacturing according to claim 8, wherein the first deposition process and the second deposition process are performed successively using a same sputtering device.

12. The method of manufacturing according to claim 8, wherein
the forming the contact structure in the fourth process further includes etching back the titanium nitride film and the titanium silicide film using the metal plug as a mask and exposing a top surface of the interlayer insulating film, and
in the forming the first electrode in the fifth process, the first electrode is formed on the top surface of the interlayer insulating film, in contact with the interlayer insulating film.

13. The method of manufacturing according to claim 8, wherein the first deposition process is performed under an atmosphere of a temperature not higher than 300 degrees C.

14. The method of manufacturing according to claim 8, further comprising:
as an irradiation process, irradiating the semiconductor substrate with radiation after the first annealing process; and
as a second annealing process, performing a heat treatment under a hydrogen atmosphere after the irradiation process and thereby adjusting a predetermined recovery characteristic of a parasitic diode formed by the pn junction.

15. The method of manufacturing according to claim 8, wherein the second deposition process is performed under an atmosphere of a temperature not higher than 300 degrees C.
